(19) United States
(12) Patent Application Publication
(10) Pub. No.: US 2009/0024978 A1
(43) Pub. Date: Jan. 22, 2009

(54) SEMICONDUCTOR DEVICE MASK, METHOD OF FORMING THE SAME AND METHOD OF MANUFACTURING SEMICONDUCTOR DEVICE USING THE SAME

(76) Inventor: Young-Mi Kim, Gwangsan-gu (KR)

Correspondence Address: SHERR & VAUGHN, PLLC, 620 HERNDON PARKWAY, SUITE 200, HERNDON, VA, 20170, US

(21) Appl. No.: 12/169,577

(22) Filed: Jul. 8, 2008

(30) Foreign Application Priority Data
Jul. 20, 2007 (KR) 10-2007-0072548

(51) Int. Cl. G06F 17/50; H01L 21/027

(52) U.S. Cl. 716/19; 438/758; 257/E21.026

(57) ABSTRACT

Embodiments relate to a semiconductor device mask in which an optical proximity correction (OPC) process is performed to compensate for varying degrees of planarization of a lower layer and a method of forming a mask pattern. In embodiments, a method of forming a semiconductor device mask includes dividing a semiconductor substrate into a plurality of local regions. Densities of patterns of the local regions are determined. A degree of dishing of the local regions is also determined. The local regions are classified into a first group in case where the degree dishing of the local regions are within an error range and a second group in case where the degree of dishing of the local regions exceed the error range. A mask data preparation process is performed with a size retrieved from a basic database in the first group. A mask data preparation sizing rule different from the mask data preparation process is applied to the second group. An optical proximity correction process is performed using a database of the first group and the second group. A semiconductor device mask according to an embodiment is formed using a semiconductor device mask formation process.

The present application claims priority under 35 U.S.C. 119 to Korean Patent Application No. 10-2007-0072548 (filed on Jul. 20, 2007), which is hereby incorporated by reference in its entirety.

### BACKGROUND

With the fast growth of information media such as computers, semiconductor devices have been rapidly developed in recent years. In terms of function, semiconductor devices are required to provide high-speed operation with mass storage and data-processing capabilities. Responding to such requirements, manufacturing technologies for semiconductor devices are being rapidly developed, with a focus on increasing integration, reliability, and speed.

Semiconductor devices are therefore becoming more miniaturized with advanced methods of large scale integration. Therefore, technologies for reducing the size (or critical dimension: CD) of metal interconnections are attracting more attention for contributions to the large scale integration of the devices.

### SUMMARY

Embodiments relate to a semiconductor device mask in which an optical proximity correction (OPC) process is performed to compensate for varying degrees of planarization of a lower layer and a method of forming a mask pattern. Embodiments relate to a method of manufacturing a semiconductor device using a mask formed by adjusting a target CD of a portion in which a dishing effect occurs on a lower layer.

In embodiments, a method of forming a semiconductor device mask includes dividing a semiconductor substrate into a plurality of local regions. Densities of patterns of the local regions are determined. A degree of dishing of the local regions is also determined. The local regions are classified into a first group in case where the degree dishing of the local regions are within an error range and a second group in case where the degree of dishing of the local regions exceed the error range. A mask data preparation process is performed with a size retrieved from a basic database in the first group. A mask data preparation sizing rule different from the mask data preparation process is applied to the second group. An optical proximity correction process is performed using a database of the first group and the second group. A semiconductor device mask according to an embodiment is formed using a semiconductor device mask formation process.

In embodiments, a method of manufacturing a semiconductor device using a mask includes forming a photoresist layer comprising a planarization region and a dishing region over a semiconductor substrate. A mask is disposed over the photoresist layer. A first exposure region is defined in which an upper critical dimension width is equal to a lower critical dimension width in the planarization region using the mask. A second exposure region is defined in which a lower critical dimension width is narrower than an upper critical dimension width in the dishing region. The photoresist layer is developed to remove a photoresist of the first exposure region and the second exposure region.

Embodiments can improve a photo process margin by performing an OPC process according to a degree of planarization of a lower layer. Embodiments can previously determine and remove factors affecting a photo process through an OPC process by taking into consideration a height difference factor generated over a surface of a semiconductor device, to reduce a defect rate.

### DRAWINGS

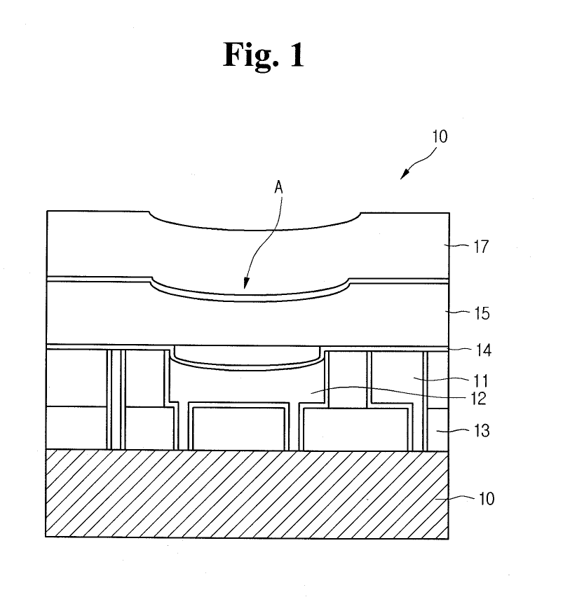

Example FIG. 1 is a cross-sectional view of a metal interconnection over which an interlayer dielectric is disposed in a semiconductor device.

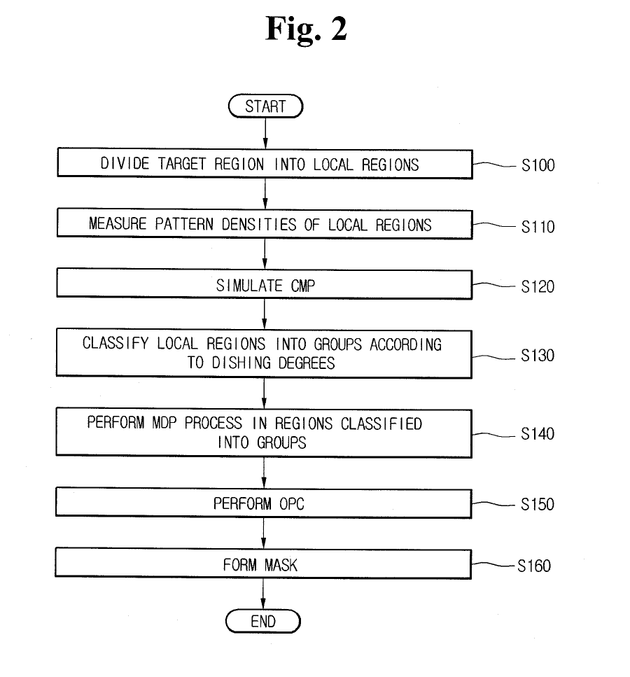

Example FIG. 2 is a cross-sectional view illustrating an exposure process using a mask pattern 20 designed through an OPC process in a semiconductor device.

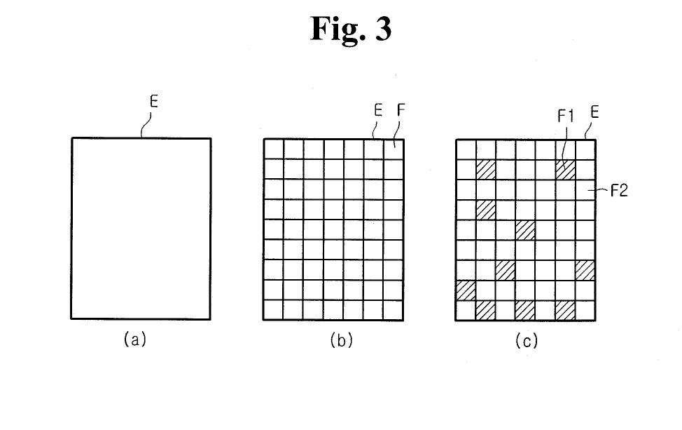

Example FIG. 3 is a flowchart illustrating a process of forming a semiconductor device mask according to embodiments.

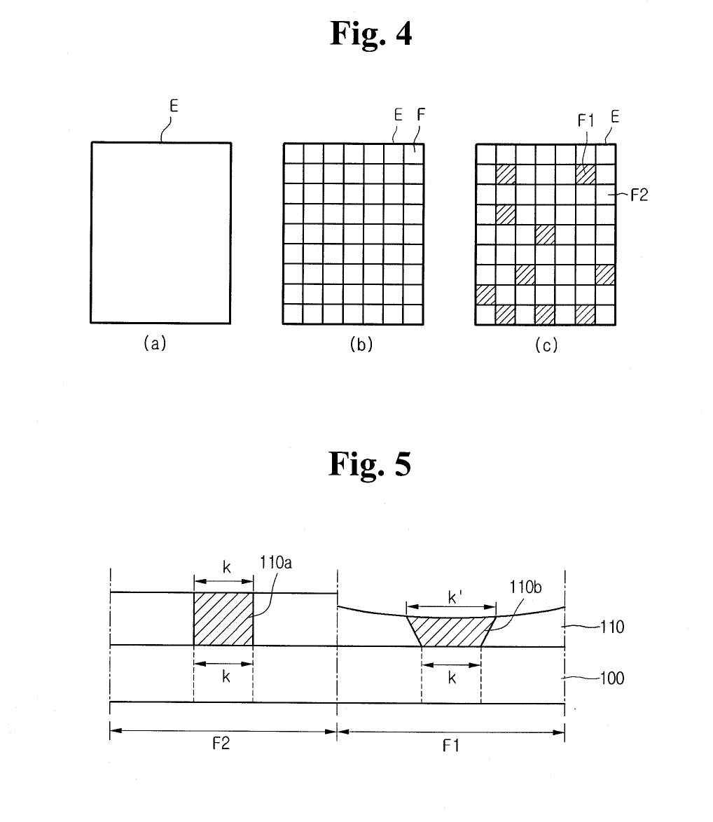

Example FIG. 4 is a plan view of semiconductor device mask pattern models including a plurality of local regions according to embodiments.

Example FIG. 5 is a cross-sectional view of a photoresist pattern formed using a semiconductor device mask pattern according to embodiments.

### DESCRIPTION

Hereinafter, a semiconductor device mask, and a method of forming the same and a method of manufacturing a semiconductor device using the same will be described in detail with reference to the accompanying drawings. Example FIG. 1 is a cross-sectional view of a metal interconnection over which an interlayer dielectric is disposed in a semiconductor device.

Referring to example FIG. 1, a first interlayer dielectric 13 including a trench is disposed on a substrate 10. A metal material has been used to fill the trench to form metal interconnections 11 and 12. A second interlayer dielectric 15 may be disposed over the metal interconnections 11 and 12. A diffusion barrier layer 14 may be disposed over a contact surface between the metal interconnections 11 and the 12 and the interlayer dielectrics 13 and 15. The substrate 10 may include a lower structure including a semiconductor substrate, a dielectric, and an interconnection.

After the second interlayer dielectric 15 is deposited, a chemical mechanical polishing (CMP) process may be performed to planarize a surface of the resulting structure. A photoresist 17 may coated over the dielectric 15. An exposure process and a development process may be performed to selectively pattern the photoresist 17. An etching process may be performed to form a trench in the second interlayer dielectric 15. A metal interconnection may be formed over the first interlayer dielectric 13.

When the CMP process is performed, a region in the lower structure in which a metal pattern is wide may be extremely dished. A periphery region of the metal pattern may be only slightly dished. As a result, it is difficult to obtain the desired planarization of the device. This is because the CMP process strongly depends on the substrate material and any height difference. It is therefore difficult to adjust process parameters, and differential dishing rates may become large.

Referring to example FIG. 1, the wide metal interconnection 12 is extremely dished, and the second interlayer dielectric 15 is affected by the dishing effect. A mask pattern may be used for patterning the photoresist 17. The mask pattern (also referred to as a “reticle”) may be designed using an optical proximity correction (OPC) process.

When the exposure process is performed using a diffraction phenomenon of light, an image of a lay-out pattern for a circuit is transferred onto the substrate. The transferred pattern is different from the actual mask pattern. Furthermore, the more a distance between adjacent patterns on the mask pattern decreases, the more the difference between the lay-out pattern and the actual mask pattern increases due to mutual influence between the adjacent patterns. This phenomenon is called the “optical proximity effect” (OPE). To correct the optical proximity effect, a pattern size or an edge region of the mask pattern may be adjusted by applying an additional simulation to CAD data for designing the mask to perform the OPC process so that the CAD data approaches the mask pattern data.

Example FIG. 2 is a cross-sectional view illustrating an exposure process using a mask pattern 20 designed with an OPC process in a semiconductor device. To obtain a relatively fine metal interconnection, a light source having a relatively short wavelength may be used in lithography equipment. To clearly expose a metal interconnection, as the resolution of a mask pattern 20 increases, the depth of focus (DOF) decreases.

Referring to example FIG. 2, light L1 and L2 passing through the mask pattern 20 is converged at points D1 and D2, respectively. When focal points are converged in a region “B” of the photoresist 17 according to the DOF, accurate exposure and development processes can be performed. When it is assumed that open regions of the mask pattern 20 are equal in size, an optimum position of the focal points is located at a point “C”. However, when a height difference A exists over a surface of the photoresist 17 disposed over the interlayer dielectric 15, a focal point of the light L2 is located outside the surface of the photoresist 17. Thus, the accurate exposure process cannot be performed.

In embodiments, one or more regions are identified in which a height difference occurs over the surface of the photoresist 17 due to the dishing effect as described above. When the mask pattern corresponding to these regions is formed, an OPC is designed with consideration towards defocusing to secure a sufficient photo process margin. Thus, patterns having a desired CD can be formed over a lower layer that is not flat.

Example FIG. 3 is a flowchart illustrating a process of forming a semiconductor device mask according to embodiments, and example FIG. 4 is a plan view of semiconductor device mask pattern models including a plurality of local regions according to embodiments. In embodiments, excellent patterns may be obtained even if a layer within a semiconductor device is not flat.

For example, the semiconductor device may include a metal interconnection layer, an interlayer dielectric 100, and a photoresist layer. The metal interconnection layer may be formed over a semiconductor substrate. The interlayer dielectric 100 may be formed over the metal interconnection layer. The photoresist layer may be formed over the interlayer dielectric 100 to selectively pattern the interlayer dielectric 100. When the photoresist layer is patterned, an etching process may be performed to form a trench that is to be filled with a metal interconnection in the interlayer dielectric 100.

When the exposure process is performed relying on a diffraction phenomenon of light, the transferred image of a lay-out pattern for a circuit on a substrate (wafer) is different from an actual mask pattern. A difference between the image of the lay-out pattern and the actual mask pattern occurs because it is affected by different planarization degrees of the photoresist layer in each of the regions as well as the OPE as described above.

Referring to example FIGS. 3 and 4, a process of forming a semiconductor device mask will now be described. In operation S100, a lay-out region E (i.e., mask pattern region) of the semiconductor device is divided into a plurality of local regions F having a predetermined size.

In operation S110, a density and size of a metal interconnection pattern constituting a lower structure are measured in each of the divided local regions. Here, when the density and size of the metal interconnection pattern are measured with respect to a dummy pattern disposed between a main pattern region and an auxiliary pattern region, accurate values can be obtained.

When a CMP process is performed on a metal interconnection layer constituting the lower structure of the semiconductor device, a region in which a metal interconnection is wide, or a region in which small metal interconnections are densely disposed, may have a height difference due different dishing rates between adjacent regions. This causes non-uniform planarization. Thus, the interlayer dielectric and the photoresist formed thereon also have a height difference due to the effect of the lower structure.

When the CMP process is performed on the metal interconnection layer of the semiconductor device, the degree of planarization of a dishing surface is first determined. Since an additional OPC process must be performed in a local region in which a height difference occurs, factors such as the density and size of the metal interconnection pattern are used to determine the planarization degree of the dishing surface.

In operation S120, a CMP simulation program is executed to predict the planarization degree of the dishing surface. The planarization degree of the local region can be predicted by inputting the facts such as the measured density and size of the metal interconnection pattern into the program in consideration of the dummy region simulated with the program.

When the degree of planarization of the local region is predicted, the degree of planarization is compared with reference values. In operation S130, a local region F1 (hereinafter, referred to as a “first group region”) in which a height difference occurs and a region F2 (hereinafter, referred to as a “second group region”) in which a height difference does not occur are classified separately from each other. The local regions may be further classified into a third group region, a fourth group region, or more according to a number of the generated height differences. The reference values are previously set height difference values affecting a DOF of light utilized for a lithography process.

In operation S140, a mask data preparation (MDP) process is performed on the regions classified into the first and second group regions F1 and F2. A MDP sizing rule is applied differently according to pattern density. A sizing rule having a sufficient margin may be applied in consideration of defocusing so that pattern collapse does not occur.

The OPC process is performed while maintaining an existing database size with respect to a region, in which the pattern density is within an average error range, of the classified group regions. Different OPC rules (programs) are applied to the classified first group region F1 and second group region F2, respectively.

As describe above, the MDP process is respectively performed in consideration of the regions in which the dishing effect occurs to set up the database. When the MDP process is performed in the first group region F1 and the second group region F2, each of the local regions is adjusted to an original division position (corresponding to the lay-out region E) to complete an entire mask pattern model.

In operations S150 and S160, the OPC process is performed on the basis of the completed mask pattern model to obtain optimized mask patterns in the semiconductor device according to embodiments. Both a rule based OPC process, suggesting a rule for each pattern size, and a model based OPC process depending on a simulation model may be used as the OPC process according to embodiments. For example, the rule based OPC process is adapted to a memory device having simple and repeated circuit patterns, because data is easily processed. The model based OPC process is adapted to a logic device having various circuit patterns because accuracy of the patterns is high.

Embodiments do not vary a DOF of a determined dishing region. Instead, patterns are formed with a desired CD width using the photoresist pattern formed by defocused DOF in consideration of the determined dishing region. That is, when a focal point is focused within a DOF margin, an upper CD width is nearly equal to a lower CD width in an exposure region of the photoresist. When the focal point is defocused within the DOF margin, the upper CD width is not nearly equal to the lower CD width.

In embodiments, a photoresist pattern is formed having an opening in which the lower CD width is greater than the upper CD width in a region in which the dishing effect occurs. Thus, the lower CD width of the opening of the photoresist pattern matches a CD width of a desired pattern to form a contact hole having the same CD width as the lower CD width of the opening in the interlayer dielectric when an etching process is performed using the photoresist pattern as a mask.

Example FIG. 5 is a cross-sectional view of a photoresist pattern formed using a semiconductor device mask pattern according to embodiments. Patterns having the same size will be disposed over a substrate 100 including a first group region F1 in which a dishing effect occurs and a second group region F2 in which the dishing effect does not occur. An existing MDP process is performed in the second group region F2. A lay-out is corrected in consideration of a dishing effect in the first group region F1.

A sizing rule having a sufficient margin is applied to the first group region F1 in consideration of defocusing so that pattern collapse does not occur. When a photoresist layer 110 disposed over the substrate 100 is exposed using a mask manufactured by the above-described method, a lower CD width k is smaller that an upper CD width k′ in a first exposure region 110b of the first group region F1. Since a focal point is focused within a FOG in a second exposure region 110a of the second group region F2, the lower CD width k is nearly equal to the upper CD width k′.

A photoresist of the exposure region is removed on the photoresist layer 110 using a positive photoresist. Therefore, when the substrate, e.g., an interlayer dielectric is etched using the photoresist pattern as an etch mask, the lower CD width of the first exposure region 110b of the photoresist layer 110 can be equal to that of the second exposure region 110a of the photoresist layer 110 to obtain patterns having a desired width.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
dividing a semiconductor substrate into a plurality of local regions;
determining densities of patterns of the local regions;
determining a degree of dishing of the local regions;
classifying the local regions into a first group where the degree dishing of the local regions are within an error range and a second group where the degree of dishing of the local regions exceed the error range;
performing a mask data preparation process with a size retrieved from a basic database in the first group, and applying to the second group a mask data preparation sizing rule different from the mask data preparation process for the first group; and
performing an optical proximity correction process using a database of the first group and the second group.

2. The method of claim 1, wherein, in the determining of the densities of the patterns of the local regions, the densities of dummy patterns formed over the semiconductor substrate are determined.

3. The method of claim 1, wherein the first group is designed so that a focal point is disposed within a depth of focus margin, and the second group is designed so that a focal point is disposed outside the depth of focus margin.

4. The method of claim 1, wherein, in determining the degree of dishing of the local regions, a chemical mechanical polishing simulation tool is used.

5. The method of claim 1, wherein a local region with a density or width of a pattern is relatively higher than those of other local regions is determined to be extremely dished.

6. The method of claim 1, wherein a local region with a density or width of a pattern is relatively wider than those of other local regions is determined to be extremely dished.

7. The method of claim 1, wherein the patterns comprise trench patterns for forming a metal interconnection formed over an interlayer dielectric.

8. An apparatus comprising:
regions of a semiconductor mask comprising mask patterns of a first group with corresponding exposure pattern densities over a semiconductor substrate; and
regions of a semiconductor mask comprising mask patterns of a second group with corresponding exposure pattern densities over a semiconductor substrate, wherein a mask data preparation sizing rule of the first group is different from that of the second group.

9. The apparatus of claim 8, wherein the first group and the second group comprise local regions.

10. The apparatus of claim 8, wherein a degree of dishing of the semiconductor substrate corresponding to local regions of the first group is within an error range, and a degree of dishing of the semiconductor substrate corresponding to local regions of the second group exceeds the error range.

11. The apparatus of claim 8, wherein a photoresist layer is disposed over a semiconductor substrate, and an upper critical dimension width is equal to a lower critical dimension width in a first exposure region of the photoresist layer disposed in the first group, and an lower critical dimension width is narrower than an upper critical dimension width in a second exposure region of the photoresist layer disposed in the second group.

12. The apparatus of claim 11, wherein the photoresist layer comprises a positive photoresist.

13. A method comprising:
forming a photoresist layer comprising a planarization region and a dishing region over a semiconductor substrate;
disposing a mask over the photoresist layer;
defining a first exposure region in which an upper critical dimension width is equal to a lower critical dimension width in the planarization region using the mask and a second exposure region in which a lower critical dimension width is narrower than an upper critical dimension width in the dishing region; and
developing the photoresist layer to remove a photoresist of the first exposure region and the second exposure region.

14. The method of claim 13, wherein a focal point is disposed within a depth of focus margin in the first exposure region, and a focal point is disposed outside the depth of focus margin in the second exposure region.

15. The method of claim 13, wherein the lower critical dimension width of the first exposure region is equal to that of the second exposure region.

16. The method of claim 13, wherein the mask is formed by:
dividing a semiconductor substrate into a plurality of local regions;
determining densities of patterns of the local regions;
determining a degree of dishing of the local regions;
classifying the local regions into a first group where the degree dishing of the local regions are within an error range and a second group where the degree of dishing of the local regions exceed the error range;
performing a mask data preparation process with a size retrieved from a basic database in the first group, and applying to the second group a mask data preparation sizing rule different from the mask data preparation process for the first group; and
performing an optical proximity correction process using a database of the first group and the second group.

17. The method of claim 13, wherein the photoresist layer comprises a positive photoresist.

18. The method of claim 13, wherein a local region with a density or width of a pattern is relatively higher than those of other local regions is determined to be extremely dished.

19. The method of claim 13, wherein a local region with a density or width of a pattern is relatively wider than those of other local regions is determined to be extremely dished.

20. The method of claim 13, wherein the patterns comprise trench patterns for forming a metal interconnection formed over an interlayer dielectric.
